(19) United States
(12) Patent Application Publication
(10) Pub. No.: US 2003/0058910 A1
(43) Pub. Date: Mar. 27, 2003

(54) Stripe laser diode element

(76) Inventors: Stefan Gruber, Bad Abbach (DE); Heerlein Martin Jorg, Regensburg (DE); Peter Unger, Ulm (DE)

Correspondence Address: SCHIFF HARDIN & WAITE, 6600 SEARS TOWER, 233 S WACKER DR, CHICAGO, IL, 60606-6473, US

(21) Appl. No.: 10/169,289

(22) PCT Filed: Dec. 22, 2000
(86) PCT No.: PCT/DE00/04592

(30) Foreign Application Priority Data
Dec. 30, 1999 (DE) 199 63 807.1

(51) Int. Cl. H01S 5/00

(52) U.S. Cl. 372/46

(57) ABSTRACT

A stripe laser diode element is provided that comprises a longitudinal propagation direction in the main propagation direction of a laser light and comprises contacts on a surface in the longitudinal propagation direction in order to impress a current into the element. The surface is limited transversely to the longitudinal direction by sidewalls in whose region an absorption zone is formed.

The invention is directed to a stripe laser diode element according to the preamble of patent claim 1.

J. Heerlein, R. Jäger and P. Unger, Single-Mode AlGaAs—GaAs Lasers using Laterad [sic] confinement by Native-Oxide Layers, IEEE photonics technology letters, vol. 10, No. 1, April 1997, page [sic] 498-500, discloses a known structure of a stripe laser diode element. Given the disclosed structure, an n-doped AlGaAs cladding layer is applied on a GaAs substrate. An AlAs layer is applied thereover, whereby the active region of the laser diode is formed therebetween. The laser light is generated in this active region by impressing a current. A p-doped AlGaAs cover or, respectively, cladding layer is applied on the AlAs layer. A contact is applied thereon in order to be able to impress a current. In order to avoid a current spread in this laser element constructed in a standard way, a trench 90 that extends to the AlAs layer is introduced through the upper layers with an etching process. The spacing of two trenches 90 constitutes the width of a laser stripe 100 (stripe laser diode element).

The AlAs layer is oxidized from the trenches 90 toward the middle of the stripe by means of water vapor oxidation. These oxidized regions represent a diaphragm that limits the current path through the component and prevents the aforementioned current spread. Although the lateral wave guidance is set with the assistance of the oxide diaphragm, it has been observed in the described element that unwanted lateral reflections occur at the sidewalls of the trenches 90. In some operating ranges, these considerably deteriorate the beam quality.

Accordingly, an object of the invention is to improve a stripe laser diode arrangement of the above-described species such that the aforementioned occurrence of reflections at the lateral edges is prevented to the farthest-reaching extent with simple means.

This object is inventively achieved with the measures recited in patent claim 1.

By providing an absorption zone in the region of the sidewalls, the light that is laterally incident here and not propagated in the emission direction of the laser is absorbed, as a result whereof the reflection is prevented to the farthest-reaching extent.

Further advantageous embodiment [sic] of the invention are recited in the dependent patent claims. As a result thereof that the absorption zone comprises a changing absorption intensity orthogonally to the longitudinal propagation direction and current direction, an abrupt change of the refractive index caused by the absorption zone is prevented, as a result whereof the occurrence of reflections is largely prevented.

The application of an absorption layer on the sidewalls enables a very simple manufacture of the absorption zone. By forming the absorption zone with implantation, the absorption zone is generated with a known, self-aligning method, which likewise highly simplifies the manufacture of the absorption zone.

In that the sidewalls proceed away from the surface at an obtuse angle therefrom, a degree of absorption of the absorption layer that varies transversely to the longitudinal propagation direction likewise arises, as a result whereof the occurrence of reflections is likewise diminished further.

The invention is explained below with reference to the drawing on the basis of exemplary embodiments.

Shown are:

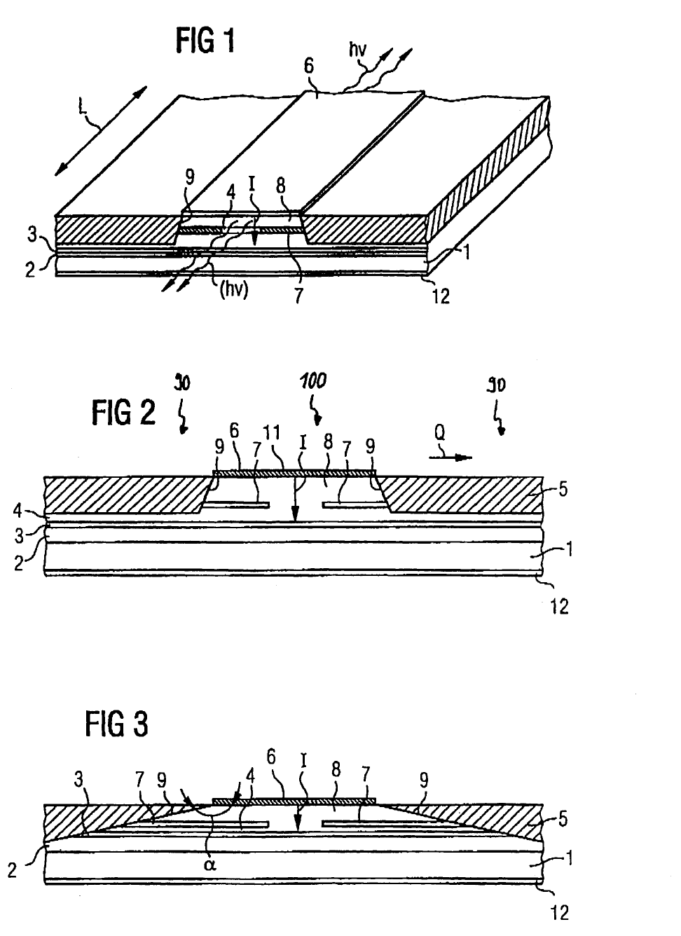

FIG. 1 a perspective view of an inventive exemplary embodiment of a stripe laser diode element;

FIG. 2 the first exemplary embodiment in section;

FIG. 3 a second inventive exemplary embodiment;

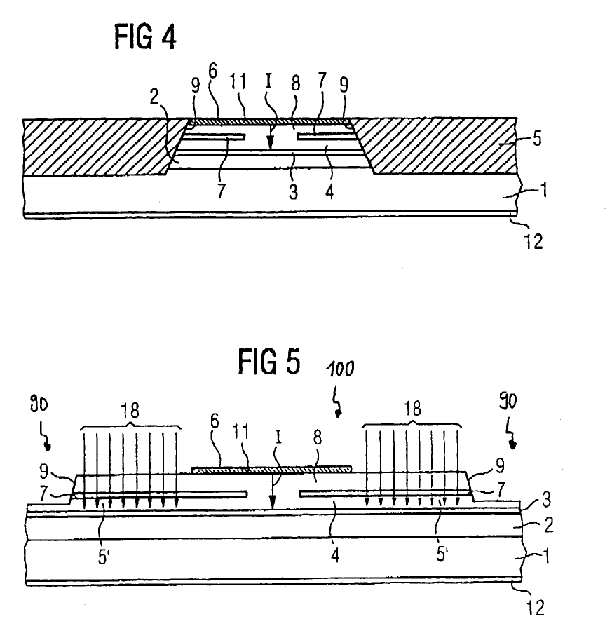

FIG. 4 a third inventive exemplary embodiment; and

FIG. 5 a fourth inventive exemplary embodiment.

FIG. 1 shows a perspective view of the basic structure of the first inventive exemplary embodiment of the laser diode element, whereby further elements are shown in FIG. 2 and are explained with reference thereto.

For a better understanding of the illustrated structure, the basic manufacturing method of the illustrated structure is explained below. An n-doped AlGaAs layer 2 is applied on a substrate 1 that is made of GaAs. An AlAs layer 4 is situated thereabove, as a result whereof an active zone 3 forms between the layer 4 and the layer 2. A p-doped AlGaAs layer 8 is applied onto the layer 4, said layer 8 being in turn covered by a contact 6. The structure of a laser diode has thus been fundamentally produced. The current for setting the occupancy inversion flows between the contacts 6 and 12, whereby the laser light is generated in the active zone 3. Light waves of the laser light form in the direction of a longitudinal propagation direction L. The exact description of a laser diode is foregone here and the knowledge thereof is presumed to be self-evident for a person skilled in the art. In order to limit the current path and, thus, the region wherein the laser light arises transversely relative to the longitudinal propagation direction L, parallel trenches 90 are introduced with an etching process in the direction of the longitudinal propagation direction L before the contacts 6 and 12 are applied.

Proceeding from the sidewalls of the laser stripe that has arisen, the AlAs layer 4 is oxidized with an oxidation process in such a way that diaphragms 7 form proceeding from the sidewalls 9. Due to the aperture of the diaphragm 7, the current is the direction I between the contacts is limited to an extremely narrow region.

In order to guide the optical wave transversely relative to the propagation direction, the active zone together with the AlAs layer 4 is surrounded by n-doped or, respectively, p-doped AlGaAs zones 8 or, respectively, 2. These layers serve the purpose of holding the laser light in the layer 4, which is referred to below as waveguide layer 4. The two layers 2 and 8 are referred to below as upper cover layer 8 and lower cover layer 2.

In order to prevent the occurrence of stray light by reflection at the sidewalls 9 that was explained in the introduction to the specification to the farthest-reaching extent, the trench 90 is filled with an absorbent layer that, for example, is composed of Si and/or Ge. This layer 5 serves for absorption and is referred to below as absorption layer 5. The reflection at the sidewalls 9 of the laser stripe is prevented to the farthest-reaching extent by the absorption of this layer. In order to improve this even further, the lateral absorption intensity of the absorption layer 5 is varied transversely relative to the longitudinal propagation direction L. In the exemplary embodiment as shown in FIG. 2, for example, this is set by a varying Si/Ge ration in direction Q. in the exemplary embodiment according to FIG. 3, in contrast, this is generated by very flat sidewalls 9, corresponding to an obtuse angle α at the surface 11 to the contact 6. The second, third and fourth exemplary embodiment according to FIGS. 3, 4 and 5 differ, further, on the basis of trenches 90 of different depth. In the first exemplary embodiment, the trench 90 and, thus, the absorption layer 5, is situated only in the region of the upper cover layer 8. Compared thereto, the trench 90 is introduced down under the active zone 3 or into the substrate 1 both in the second exemplary embodiment as well as in the third exemplary embodiment according to FIG. 4.

In the fourth exemplary embodiment according to FIG. 5, the absorption zone 5′ is produced in the following way. The structure is essentially the same as in the preceding exemplary embodiments, whereby identical reference characters refer to the same elements. In the exemplary embodiment shown in FIG. 5, the contact 6 on the surface 11 is not conducted up to the sidewalls 9. In this way, the absorption zone 5′ can be generated under the diaphragms 7 by ion implantation. The contact 6 is thereby used for the alignment of the implantation, as a result whereof an automatically self-aligning method derives. The implantation can thereby be set such that an absorption profile that varies transversely relative to the longitudinal propagation direction is produced.

Of course, the fourth exemplary embodiment can be combined with the previously described exemplary embodiments.

It must be pointed out that the invention is essentially directed to providing the absorption zone 5 or, respectively, 5′ and these can also be applied given other stripe laser arrangements that deviate from the layer sequence that has been presented.

1. Stripe laser diode element that comprises a contact element (6) on an upper side (11) in the main propagation direction of a laser light (hv) in order to impress a current (I) for operating the stripe laser diode element, and whose upper side (11) is limited transversely relative to the longitudinal propagation direction (L) by trenches (90) that, on the one hand, extend along the longitudinal propagation direction (L) and, on the other hand, extend in the direction to the substrate (1) on which the stripe laser diode element is constructed and generate sidewalls (9) of the laser stripe (100), characterized in that a radiation absorption zone (5; 5′) is formed in the region of the sidewalls (9).

3. Stripe laser diode element according to claim 1, characterized in that the absorption zone (5) is formed as absorption layer in the trenches (90).

3. Stripe laser diode element according to one of the claims 1 and 2, characterized in that the absorption zone (5; 5′) exhibits a variable absorption intensity in a direction orthogonal to the longitudinal propagation direction (L) and relative to the current direction (I).

4. Stripe laser diode element according to one of the claims 1 and 2, characterized in that the absorption zone (5′0 is generated by ion implantation into the laser stripe in the region of the sidewalls (8).

5. Stripe laser diode element according to one of the preceding claims, characterized in that the sidewalls (9) spread away from the surface (11) at an obtuse angle (α).
